(19) United States
(12) Patent Application Publication
(10) Pub. No.: US 2026/0221378 A1
(43) Pub. Date: Jul. 30, 2026

(54) Conveying Method, Conveyance Device, and Analysis System

(71) Applicant: Hitachi High-Tech Corporation, Minato-ku, Tokyo (JP)

(72) Inventor: Yoshinori HIGASHI, Tokyo (JP)

(21) Appl. No.: 19/146,644

(22) PCT Filed: Jan. 31, 2023
(86) PCT No.: PCT/JP2023/003076

§ 371 Date: Jul. 9, 2025

(51) Int. Cl. H01J 37/20

(52) U.S. Cl. CPC H01J 37/20; H01J 2237/20292

(57) ABSTRACT

Conveying accuracy of a mesh on which a sample to be analyzed using a charged particle beam device is mounted is improved. As a method, a conveying method includes: (a) a step of picking up and holding the mesh placed on a first placement table by a first conveying unit; (b) a step of capturing an image of the mesh held by the first conveying unit using a first imaging unit after the step (a); (c) a step of correcting a position or an angle of the mesh based on a first image acquired in the step (b); and (d) a step of mounting the mesh on a mesh holder by the first conveying unit after the step (c).

### TECHNICAL FIELD

The present invention relates to a conveying method, a conveyance device, and an analysis system, and particularly to a conveying method and a conveyance device for conveying a mesh on which a sample to be analyzed using a charged particle beam device is mounted.

### BACKGROUND ART

In recent years, miniaturization of semiconductor advanced devices is promoted. In order to observe a structure of a semiconductor advanced device, for example, a technique is known in which a sample is taken out from a wafer by a focused ion beam (FIB) device, the taken out sample is transferred (bonded) to a mesh, and the sample is observed by a scanning electron microscope (SEM).

PTL 1 (WO2021/210087) discloses that a mesh on a stage is conveyed by a manipulator and mounted on a holder, and then observation is performed by a transmission electron microscope (TEM).

### CITATION LIST

### Patent Literature

PTL 1: WO2021/210087

### SUMMARY OF INVENTION

### Technical Problem

In the related art, the mesh to which a sample piece is to be transferred is fixed to a holder manually. Therefore, positional accuracy of the mesh is poor, which causes failures such as a poor attachment angle at the time of transferring the sample piece, and a failure in a visual field of mesh recognition.

The invention has been conceived to solve the above problems, and an object of the invention is to improve conveying accuracy of a mesh.

### Solution to Problem

An outline of a representative one among embodiments disclosed in the present application will be briefly described as follows.

A conveying method according to an embodiment is a conveying method for conveying a mesh on which a sample to be analyzed using a charged particle beam device is to be mounted, which includes: (a) a step of picking up and holding the mesh placed on a first placement table by a first conveying unit; (b) a step of capturing an image of the mesh held by the first conveying unit using a first imaging unit after the step (a); (c) a step of correcting a position or an angle of the mesh based on a first image acquired in the step (b); and (d) a step of mounting the mesh on a mesh holder by the first conveying unit after the step (c).

### Advantageous Effects of Invention

According to the invention, conveying accuracy of a mesh can be improved.

### BRIEF DESCRIPTION OF DRAWINGS

FIG. 1 is a schematic view showing a conveyance device according to an embodiment.

FIG. 2 is a plan view showing the conveyance device shown in FIG. 1.

FIG. 3 is a plan view showing a mesh according to the embodiment.

FIG. 4 is a perspective view showing a mesh holder according to the embodiment.

FIG. 5 is a flowchart showing a conveying method according to the embodiment.

FIG. 6 is a flowchart showing the conveying method according to the embodiment.

FIG. 7 is a flowchart showing the conveying method according to the embodiment.

FIG. 8 is a flowchart showing the conveying method according to the embodiment.

FIG. 9 is a flowchart showing the conveying method according to the embodiment.

FIG. 10 is a flowchart showing the conveying method according to the embodiment.

FIG. 11 is a flowchart showing the conveying method according to the embodiment.

FIG. 12 is an image diagram showing an imaging result by an upper camera according to the embodiment.

FIG. 13 is a perspective view showing conveying unit according to the embodiment.

FIG. 14 is a bottom view showing the conveying unit according to the embodiment.

FIG. 15 is a bottom view showing the conveying unit after correction according to the embodiment.

FIG. 16 is a bottom view showing the conveying unit and the mesh according to the embodiment.

FIG. 17 is an image diagram showing an imaging result by a lower camera according to the embodiment.

FIG. 18 is a plan view showing a positional relationship between the mesh holder and the conveying unit when the mesh is mounted according to the embodiment.

FIG. 19 is a side view showing the positional relationship between the mesh holder and the mesh when the mesh is mounted according to the embodiment.

FIG. 20 is an enlarged plan view for illustrating the transfer of a sample piece to the mesh.

FIG. 21 is an image diagram showing an imaging result of a placement table obtained by the upper camera according to the embodiment.

FIG. 22 is a plan view illustrating conveying of a mesh from a placement table to another placement table according to Modification 1 of the embodiment.

FIG. 23 is a schematic view showing an analysis system according to the embodiment.

FIG. 24 is a schematic view showing an analysis system according to Modification 2 of the embodiment.

FIG. 25 is a schematic view showing an analysis system according to Modification 2 of the embodiment.

FIG. 26 is a plan view showing a mesh and a mesh holder according to a comparative example.

FIG. 27 is an enlarged plan view for illustrating transfer of a sample piece to the mesh according to the comparative example.

### DESCRIPTION OF EMBODIMENTS

Hereinafter, embodiments of the invention will be described in detail with reference to the drawings. In all the drawings for describing the embodiments, members having the same function are denoted by the same reference numeral, and the repeated description thereof will be omitted. In the embodiments, the description of the same or similar parts will not be repeated in principle unless particularly necessary.

An X direction (X axis) and a Y direction (Y axis) are orthogonal to each other, and both are directions along a horizontal plane. Here, a direction perpendicular to the X direction and the Y direction is referred to as a Z direction (Z axis) or a perpendicular direction.

Both a focused ion beam (FIB) and a scanning electron microscope (SEM) are devices capable of observing a fine shape. The FIB is a device capable of detecting generated secondary electrons and the like and observing a microscopic image by scanning a front surface of a sample with a finely focused ion beam. The SEM is a device capable of observing a microscopic image of a front surface of a sample by applying an electron beam to the sample. Here, since a mass of ions is larger than that of electrons, a phenomenon in which a sample is scraped off occurs during ion beam irradiation of the FIB. By utilizing this, the FIB is also used for microfabrication of a sample. A FIB-SEM on which a FIB, an SEM, and an inclinable stage are mounted is widely used as a device for preparing and observing a sample piece for TEM observation. Preparation of a sample piece by irradiation with an ion beam by the FIB is described in, for example, JP2016-50853A.

In observation of a sample using the FIB-SEM, a semicircular plate referred to as a mesh is mounted on a mesh holder, the mesh is carried into the FIB-SEM device together with the mesh holder, and then a sample piece is transferred to the mesh. As a main application by the FIB-SEM, there is automatic microsampling. The microsampling refers to preparation of a sample piece for TEM observation, and the automatic microsampling refers to a technique for automating the preparation.

The embodiments described below relate to a method for conveying a mesh from a placement table to a mesh holder at a stage before the mesh is put into the FIB-SEM device, a method for conveying the mesh carried out from the FIB-SEM device from the mesh holder to the placement table, and a conveyance device thereof. The embodiments described below relate to a method for conveying a mesh from a placement table to a mesh holder before the mesh is put into an optical sample piece transfer device or a TEM device, a method for conveying the mesh carried out from the optical sample piece transfer device or the TEM device from the mesh holder to the placement table, and a conveyance device thereof (see Modification 2).

### Embodiment

### <Configuration of Conveyance Device>

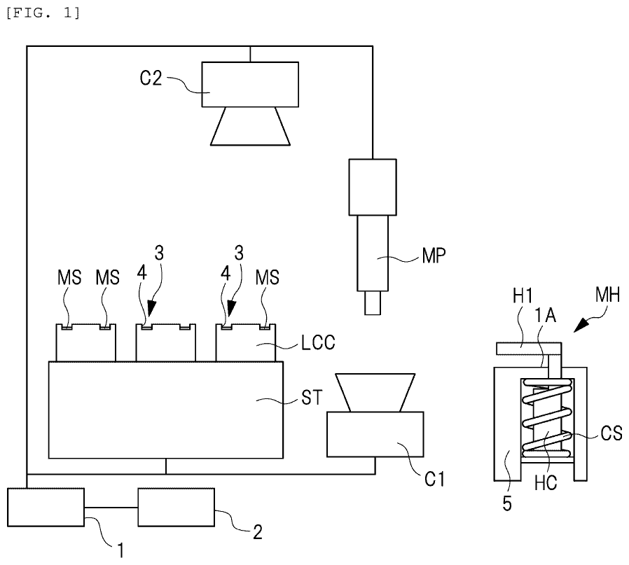

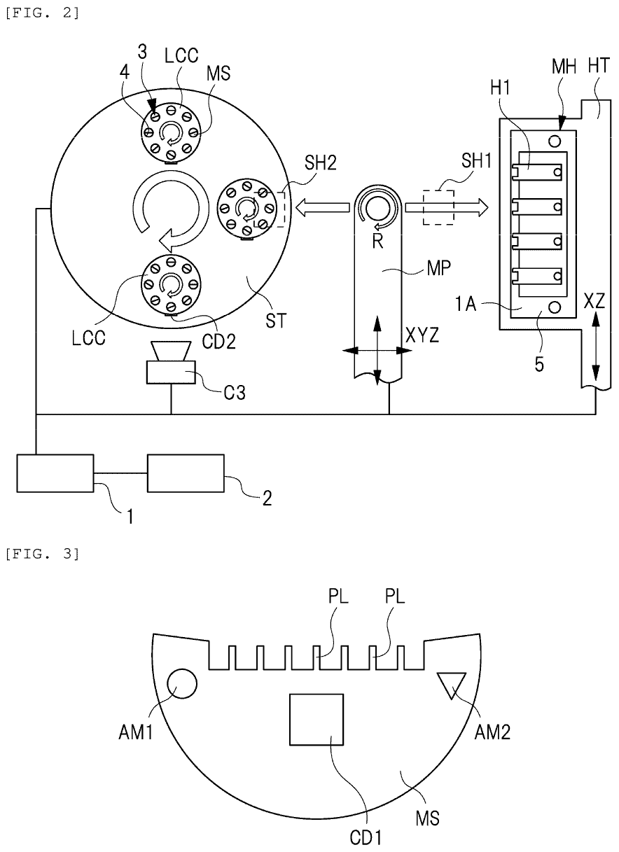

FIGS. 1 and 2 show a conveyance device according to the present embodiment. FIG. 1, which is a side view, and FIG. 2, which is a plan view, correspond to each other, and show the same conveyance device. As shown in FIGS. 1 and 2, the conveyance device according to the present embodiment includes a stage ST for meshes MS, a conveying unit (manipulator) MP that adsorbs and conveys the mesh MS at the bottom, and a mesh holder MH on which the mesh MS can be mounted.

At least one placement table LCC can be mounted on the stage ST. Here, the stage ST is provided with three placement tables LCC, and the number of placement tables LCC may be more or less than three. The stage ST is a circular rotary table rotatable about a perpendicular direction as axis, and may be a stage drivable in the X direction and the Y direction. The rotary table is excellent in space efficiency.

The placement table LCC has a circular upper surface in a plan view, and has a substantially cylindrical shape. A plurality of placement tables LCC can be placed on an upper surface of the stage ST side by side on a circular orbit around a center of the stage ST in a plan view. Each placement table LCC is axially rotatable about an axis of the cylindrical shape thereof, and on an upper surface of the placement table LCC, a plurality of placement portions 3 are arranged on a circumference about the axis. The placement portion 3 includes a recess (hole) 4 on the upper surface of the placement table LCC, and the mesh MS can be mounted on a bottom surface of the recess 4. The recess 4 is circular in a plan view and has a diameter of, for example, about 3 mm. Here, one placement table LCC has eight placement portions 3. The placement table LCC is referred to as, for example, a mesh cartridge or an LC container. The placement portions 3 (recesses 4) may be arranged in a matrix on the upper surface of the placement table LCC instead of being arranged on a circumference.

An upper surface 1A of a main body 5 of the mesh holder MH, the bottom surface of the recess 4, and a lowermost surface of the conveying unit MP are all surfaces along a horizontal plane.

The conveying unit MP picks up the mesh MS from the hole of the placement table LCC and conveys the mesh MS to the mesh holder MH. The conveying unit MP also performs a reverse operation. The conveying unit MP can be driven in the X direction, the Y direction, and the Z direction, and moves between the stage ST and the mesh holder MH. In addition, in the conveying unit MP, a tip end portion (bottom portion) for picking up the mesh MS is rotatable about the Z direction as an axis. The conveying unit MP picks up and holds the mesh MS by, for example, vacuum adsorption. The vacuum may be generated by a vacuum pump, or a vacuum generator using compressed air may be used. Since the mesh MS is small and light, it can be sufficiently adsorbed by adsorption by a vacuum generator. By monitoring an adsorption pressure, it is possible to manage adsorption success of the mesh MS. In addition to the vacuum adsorption, an adsorption method using static electricity may be used, and a method for picking up the mesh MS by sandwiching the mesh MS from above and below like tweezers may be used.

Here, a TEM mesh for conveying a sample piece by automatic microsampling will be described. FIG. 3 shows a planar shape of the mesh MS. The mesh MS is formed of a plate-shaped member having a substantially semicircular planar shape. That is, the mesh MS includes an upper surface (front surface), a lower surface (bottom surface, back surface) parallel to the upper surface, and a side surface connecting the upper surface and the lower surface. Although a semicircular mesh is described here, the mesh may be circular.

The TEM sample may be referred to as Lamella, and the mesh MS is also referred to as TEM mesh, TEM grid, Lamella Carrier, or LC. The mesh MS is a metal piece having a diameter of 3 mm, and has a half-moon-shaped comb shape. Each of the plurality of comb teeth protruding outward from an end portion of the mesh MS is a pillar (columnar portion) PL. A TEM sample piece is attached to one of the pillars PL in the FIB-SEM device.

The mesh MS is provided with an alignment mark AM1 formed of a circular through hole and an alignment mark AM2 formed of a triangular through hole in a plan view. Sizes and positions of the alignment marks AM1 and AM2 are common to all the meshes MS. Here, a case in which a shape of the alignment mark is circular and triangular will be described, and the shape of the alignment mark is not limited to these shapes. A two-dimensional code (two-dimensional matrix code, identification code) CD1 is given to the upper surface of the mesh MS.

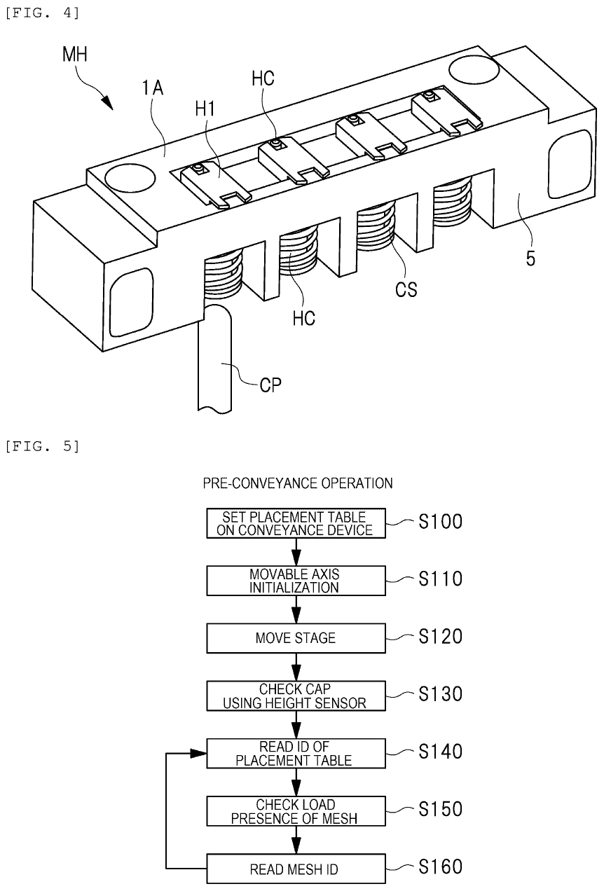

The mesh holder MH is mounted on a table HT that can be driven in the X direction and the Z direction, for example. FIG. 4 is a perspective view of the mesh holder MH. The mesh holder MH fixes the mesh MS conveyed by the conveying unit MP. One or more meshes MS can be fixed to the mesh holder MH. Here, four meshes MS can be fixed. A fixing method of the mesh MS includes a screwing method and a spring method, and the spring method is adopted here.

The mesh holder MH includes the main body 5, cylinders HC penetrating the main body 5, and mesh retainers H1 connected to upper ends of the cylinders HC on the main body 5. The mesh retainer H1 is a plate-shaped member parallel to the upper surface 1A of the main body 5. The cylinder HC and the mesh retainer H1 are biased toward a lower side of the main body 5 in the Z direction by a spring (coil spring) CS that is a biasing portion wound around the cylinder HC in the main body 5. That is, the mesh retainer H1 is biased toward the upper surface 1A of the main body 5 by the spring CS.

In the spring method, a cylinder pin CP inside a conveying system pushes up the spring CS of the mesh holder MH to generate a gap between the mesh retainer H1 and the holder. When the cylinder pin CP is lowered in a state in which the conveying unit MP inserts the mesh MS into the gap, the mesh retainer H1 is lowered, and the mesh MS is fixed (mounted) on the upper surface 1A of the mesh holder MH. The cylinder pins CP are controlled by compressed air. One or more cylinder pins CP may be provided, and a plurality of cylinder pins CP may be provided.

As shown in FIG. 1, as one of the main features of the present embodiment, the conveyance device includes a camera (lower camera) C1 for checking a posture of the mesh MS, which is disposed immediately below a conveying path of the mesh MS by the conveying unit MP. As one of the main features of the present embodiment, the conveyance device includes a camera (upper camera) C2 disposed directly above the placement portion 3 on the upper surface of the placement table LCC. The camera C2 is used to check the position of the placement portion 3 (the center position of the recess 4) or a posture of the mesh MS placed on the placement portion 3, or to read the two-dimensional code on the front surface of the mesh MS. For example, a two-dimensional code (two-dimensional matrix code, identification code) CD2 may be given to a side surface of the placement table LCC. At this time, a camera C3 (see FIG. 2) which is a code reader for reading the two-dimensional code of the placement table LCC is installed in the vicinity of the stage ST.

As shown in FIGS. 1 and 2, each of the stage ST, the conveying unit MP, the table HT, and the cameras C1, C2, and C3 is connected to a control unit 1 including, for example, a computer. More specifically, power for driving each of the stage ST, the conveying unit MP, and the table HT is connected to the control unit 1. Operations of the stage ST, the conveying unit MP, and the table HT are controlled by the control unit 1. The control unit 1 is connected to a storage unit 2. Although not shown, the control unit 1 may be connected to a display unit, an operation unit, and the like.

The camera C2 captures an image of the front surface (upper surface) of the mesh MS immediately below the camera C2 from above. That is, the camera C2 is disposed above the placement table LCC. At this time, the stage ST moves the coordinates so that the mesh MS comes directly below the camera C2. In FIG. 2, the camera C2 captures an image in a region SH2 surrounded by a broken line, for example. When imaging is performed by the camera C2, the mesh MS is illuminated by a camera light source. By the illumination, the metal mesh MS shines white during imaging, and the front surface of the placement table LCC including the front surface of the recess 4 appears black as a background. An intensity of the camera light source and an exposure time of the camera C2 are adjusted so that a contrast is created between the mesh MS and the recess 4 of the placement table LCC. In addition, when the recess 4 in which the mesh MS is not placed is imaged, the recess 4 is imaged under a brighter condition than when the mesh MS is imaged. The image captured by the camera C2 is sent to the control unit 1 and subjected to image processing.

The camera C1 captures an image of the back side of the mesh MS picked up by the conveying unit MP in a manner of looking up from below. After the mesh MS is picked up by the conveying unit MP, since the upper surface (front surface) of the mesh MS is hidden by the conveying unit MP, it is necessary to capture an image from the back side in order to recognize the posture during pickup. During imaging by the camera C1, the coordinates of the conveying unit MP are moved so that the conveying unit MP comes directly above the camera C1. That is, the camera C1 is disposed below the bottom of conveying unit MP. In FIG. 2, the camera C1 captures an image in a region SH1 surrounded by a broken line, for example. Here as well, brightness and the exposure time of the camera light source are adjusted so that a contrast is created between the mesh MS and the background. The image captured by the camera C1 is sent to the control unit 1 and subjected to the image processing.

### <Conveying Operation>

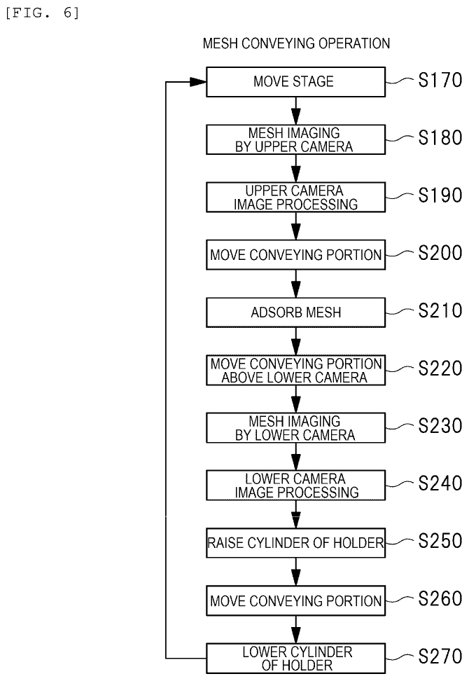

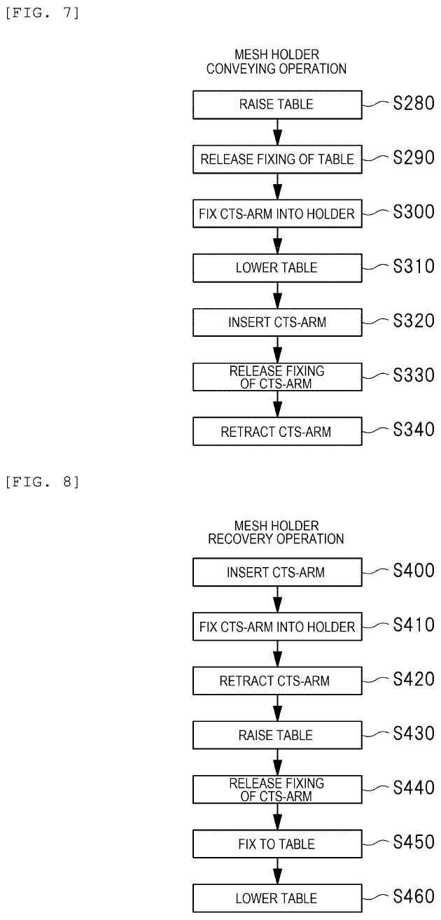

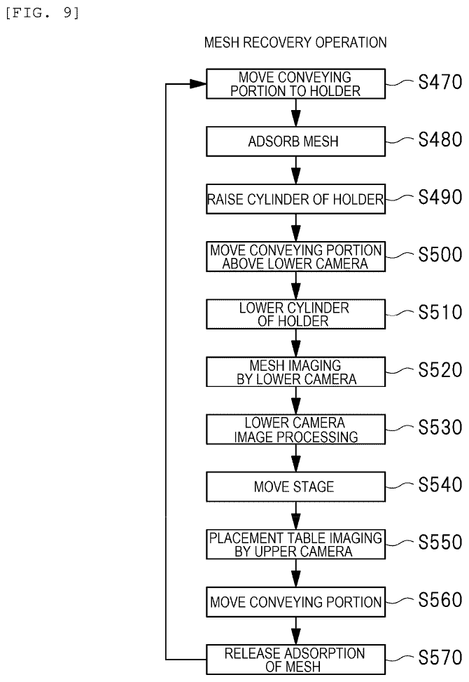

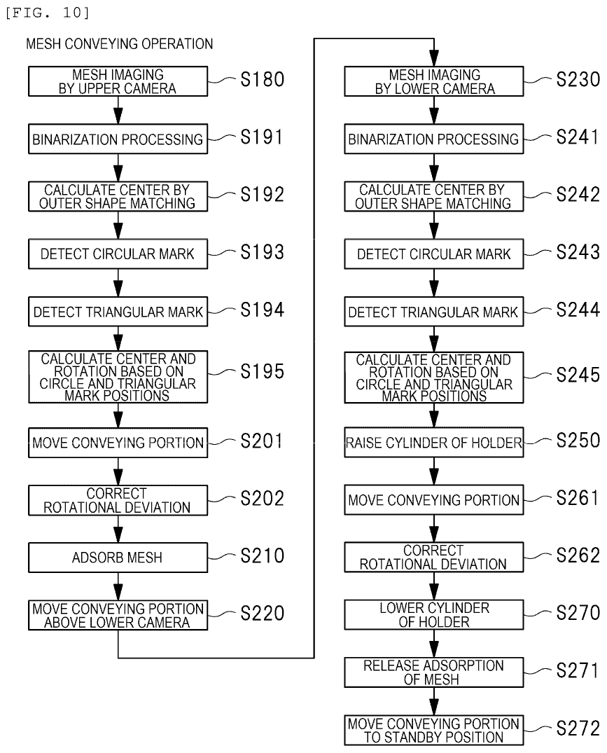

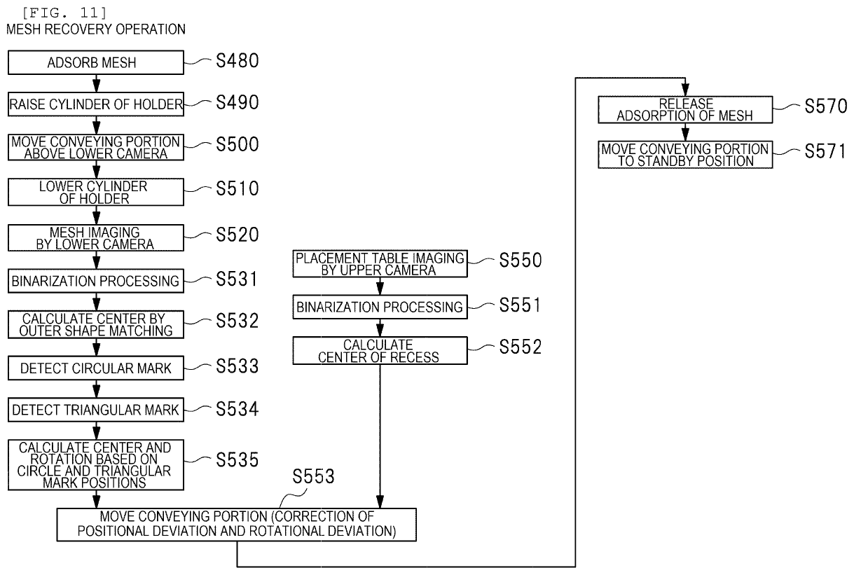

The conveying operation of the mesh performed using the conveyance device described above will be described below with reference to flows of FIGS. 5 to 11. The flows of FIGS. 5 to 7 illustrate the conveying operation before the mesh is put into the FIB-SEM device. The flows of FIG. 8 and FIG. 9 illustrate the conveying operation after the mesh is collected (carried out) from the FIB-SEM device. The flow of FIG. 10 illustrates a part of the flow of FIG. 6 more specifically. The flow of FIG. 11 illustrates a part of the flow of FIG. 9 more specifically.

First, as shown in FIG. 5, a pre-conveyance operation is performed. That is, the placement table LCC is set in a carrier transfer system (CTS) which is the conveyance device in the present embodiment before the conveying (step S100 in FIG. 5). When the mesh MS is not mounted on the placement table LCC, a mounting work is also performed.

A movable axis of the conveying system is initialized (step S110 in FIG. 5). The X axis, the Y axis, the Z axis, and the R axis (rotation axes, see FIG. 2) of the conveying unit MP correspond to movable axes. In order to perform highly accurate conveyance, an initialization operation is required.

The stage ST is moved (step S120 in FIG. 5), and the presence or absence of a cap using a height sensor is checked (step S130 in FIG. 5). The height sensor is disposed on the placement table LCC. The cap refers to a lid of the placement table LCC, and is attached to prevent dirt or scattering. If the cap remains attached to the placement table LCC, the pickup by the conveying unit MP cannot be performed, and thus the checking is performed before the conveying.

Subsequently, the stage ST is moved to read an ID of the placement table LCC (step S140 in FIG. 5). There is a placement table LCC to which an ID (two-dimensional code CD2) is given, and reading is performed by a code reader (camera C3) inside the conveyance device to associate information about the placement table LCC with information about the mesh MS inside the placement table LCC. Here, the control unit 1 stores the information about the two-dimensional code CD2 in the storage unit 2.

Subsequently, the stage ST is moved (rotated) such that the placement portion 3 of the placement table LCC comes directly below the camera C2. The camera C2 captures an image of the mesh MS placed on the placement portion 3 and checks load presence of the mesh MS (checks the presence or absence of the mesh MS) (step S150 in FIG. 5). When the image of the mesh MS matches an outer shape model registered in advance, the control unit determines that the load is present. When there is no mesh MS, the control unit 1 stores information on the absence of the mesh MS in the storage unit 2.

In parallel with the load presence check of the mesh MS, the two-dimensional code CD1 marked on the front surface of the mesh MS is also read (step S160 in FIG. 5). Since a marking position of the two-dimensional code CD1 on the front surface of the mesh MS is determined, the two-dimensional code CD1 is detected by searching a specific region of the mesh MS after posture recognition of the mesh MS. The read ID information is transmitted to the control unit 1. The control unit 1 stores the information in the storage unit 2, and associates the ID of the placement table LCC (information about the two-dimensional code CD2) with the ID of the mesh MS (information about the two-dimensional code CD1). That is, the control unit 1 stores the information in the storage unit 2 in association with each other.

ID reading of the placement table LCC, the checking of the load presence of the mesh MS, and the ID reading of the mesh MS are performed for all the placement tables LCC when a plurality of placement tables LCC are mounted. That is, steps S140 to S160 are repeated. Reading is skipped for the placement table LCC for which reading of information is completed. In addition, an operator can select not to read a specific placement table LCC.

Next, a mesh conveying operation shown in FIG. 6 is performed.

That is, in order to conveying the mesh MS, the stage ST is moved such that the mesh MS is located directly below the camera C2 (upper camera) (step S170 in FIG. 6).

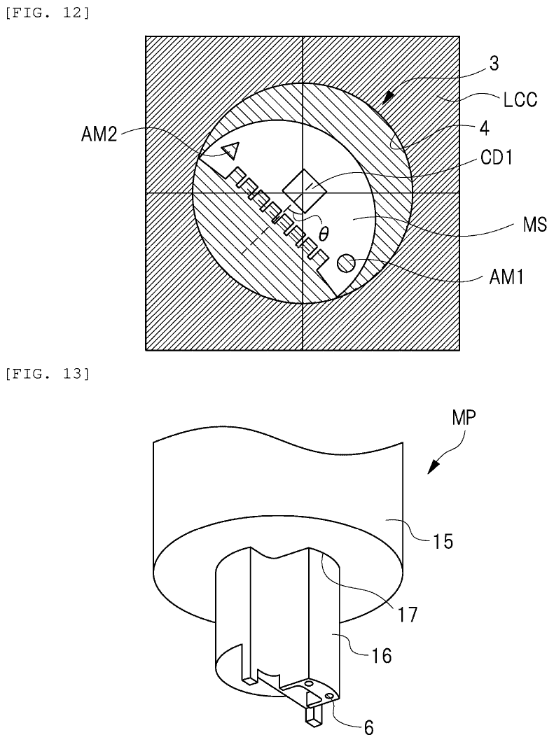

Subsequently, the mesh MS is imaged by the camera C2 (step S180 in FIG. 6). An example of an image obtained accordingly is shown in FIG. 12. In FIG. 12, it is ideal that a horizontal line and a vertical line intersect at the center of the image, and a center point of the mesh MS is located at an intersection of the horizontal line and the vertical line (center of camera angle of view). The center point of the mesh MS is the center of a circle assuming that the semicircular mesh MS is not a semicircle but a circle, and is the intersection of two broken lines shown in FIG. 12. In the example shown in FIG. 12, the center of the image (reference point, center of camera angle of view) and the center point of the mesh MS are positionally deviated in the X direction and the Y direction.

It is ideal that an arc of the semicircular mesh MS faces upward in FIG. 12. Here, the mesh MS is rotationally deviated (angularly displaced) by an angle θ formed by a vertical line and a broken line extending perpendicularly to the direction in which the pillars PL are arranged. A rotational deviation amount in FIG. 12, that is, the angle θ is, for example, 45 degrees. Ideally, the angle θ is 0 degrees.

Subsequently, the image captured by the camera C2 in step S180 is transmitted to the control unit 1, and the control unit 1 performs image processing (step S190 in FIG. 6).

Subsequently, the conveying unit MP is moved to correct positional deviation amounts in the X direction and the Y direction and a rotational deviation amount in a rotation direction of the mesh MS obtained by the image processing (step S200 in FIG. 6). When the center (reference point) of the image and the center point of the mesh MS overlap each other, the positional deviation does not occur, and the angle θ is 0 degrees and the rotational deviation does not occur, it is not necessary to correct the position and the angle in steps S190 and S200 to be described later. Even in such a case, the control unit 1 performs the image processing in step S190 and determines whether correction is necessary.

Subsequently, the conveying unit MP adsorbs the mesh MS (step S210 in FIG. 6). At this time, the conveying unit MP adsorbs the center of the mesh MS by camera image processing (the center can be set to any position other than the center).

Here, FIGS. 13 and 14 show the conveying unit MP. FIG. 14 is a diagram of a tip end (lower end) of the conveying unit MP as viewed from below. In FIG. 14, the lowermost surface of the conveying unit MP, which is a surface that can be in contact with the mesh MS, is hatched. Two hole portions 6 are provided in the lowermost surface of the conveying unit MP. When the adsorption is performed by the hole portions 6, the mesh MS is adsorbed to the lower surface. The shape of the tip end of the conveying unit MP is substantially circular in a plan view, and upper left and right portions (both shoulder portions) in FIG. 14 are hollowed out.

As shown in FIG. 13, the conveying unit MP includes a support pole 15 extending in the perpendicular direction, a hole 17 provided in a bottom surface of the support pole 15, and an adsorption nozzle 16 provided in the hole 17 extending in the perpendicular direction and movable in the perpendicular direction (up-down direction). A tip end (bottom surface) of the adsorption nozzle 16 is provided with the two holes 6.

In step S200, the conveying unit MP moves according to the positional deviation amounts in the X direction and the Y direction of the mesh MS obtained by the image processing in step S190. In step S200, the conveying unit MP rotates (for example, 45 degrees) according to the rotational deviation amount of the mesh MS obtained by the image processing in step S190 (see FIG. 15). That is, the positional deviation or the rotational deviation of the mesh MS is corrected by the movement or the rotation of the conveying unit MP.

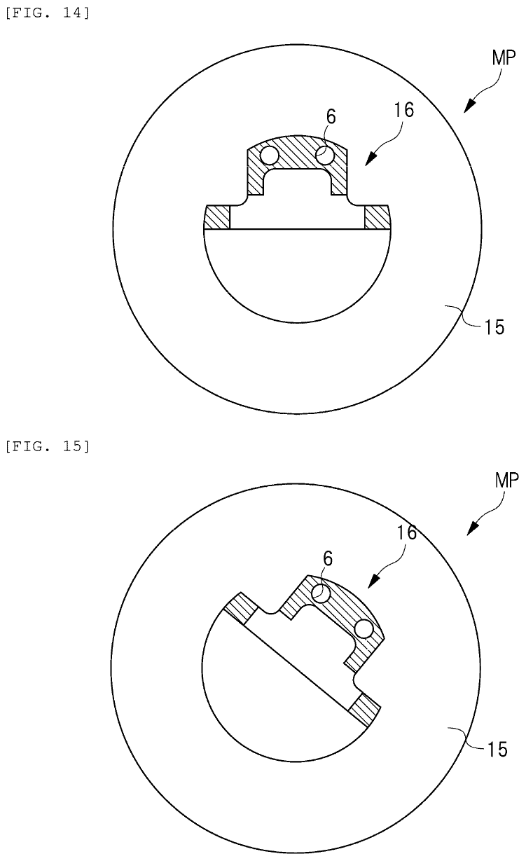

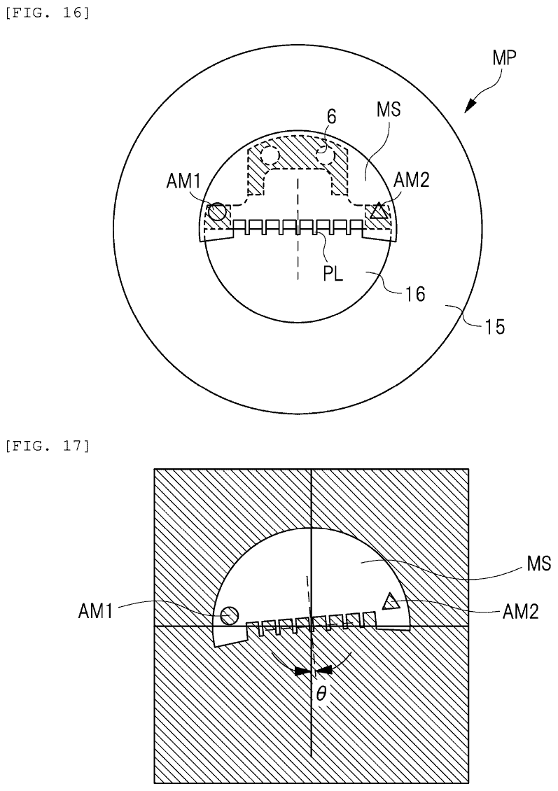

FIG. 16 shows a state in which the mesh MS is adsorbed to the tip end of the conveying unit MP in step S210. FIG. 16 shows the conveying unit MP holding the mesh MS as viewed from below, and the adsorption nozzle 16 hidden by the mesh MS is indicated by a broken line. When the mesh MS is viewed from the back side, the two-dimensional code CD1 on the upper surface of the mesh MS cannot be visually recognized.

Since a portion (pillar portion) in which the pillars PL of the mesh MS are arranged is a portion on which the sample piece is mounted, the lowermost surface of the conveying unit MP and the pillar portion during adsorption are separated from each other so that a part of the conveying unit MP does not come into contact with the pillar portion when the mesh MS is adsorbed. Specifically, the adsorption nozzle 16 having a shape that hollows out the pillar portion is used so that the pillar portion can be avoided even when the vicinity of the central portion of the mesh MS is adsorbed after rotation correction. That is, the lowermost surface of the conveying unit MP that can come into contact with the mesh MS is a region surrounding the central portion of the adsorbed mesh MS and is located in the vicinity of a circumferential portion of the semicircular mesh MS in a plan view. The tip end portion (adsorption nozzle 16) of the conveying unit MP that adsorbs the mesh MS is desirably made of a conductive material in order to prevent sticking due to static electricity.

Subsequently, when the mesh MS is adsorbed, the conveying unit MP is moved to immediately above the camera (lower camera) C1 (region SH1) (step S220 in FIG. 6). In this manner, the conveying unit MP picks up the mesh MS.

Subsequently, the back surface of the mesh MS is imaged by the camera C1 (step S230 in FIG. 6). FIG. 17 shows an example of an image obtained by the imaging. Although the positional deviation and the rotational deviation of the mesh MS are substantially eliminated by the correction performed in steps S180 to S200, the positional deviation and the rotational deviation may occur again when the adsorption is performed in step S210. Here, as shown in FIG. 17, the rotational deviation of an angle θ occurs.

Subsequently, the image is transmitted to the control unit 1, and the control unit 1 performs image processing (step S240 in FIG. 6).

Subsequently, the cylinder HC of the mesh holder MH is raised to form a gap between the mesh retainer H1 and the upper surface 1A of the main body 5 of the mesh holder MH (step S250 in FIG. 6).

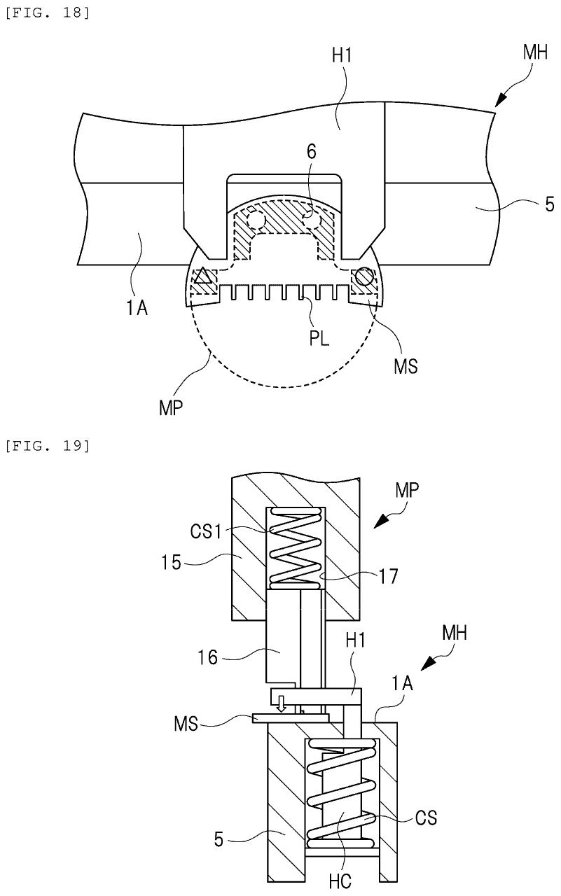

The conveying unit MP is moved so that the mesh MS enters a gap 1A (step S260 in FIG. 6). Here, as shown in FIG. 18, in a state in which the conveying unit MP and the mesh retainer H1 are separated from each other, the conveying unit MP is moved to a position overlapping the mesh MS and the mesh retainer H1 in a plan view. In FIG. 18, a portion of the conveying unit MP in which the conveying unit MP and the mesh MS are in contact with each other is hatched. In addition, a part of an outer shape of the vicinity of the tip end of the conveying unit MP is indicated by a broken line.

As shown in FIG. 19, before the time point at which the conveying unit MP is moved to the mesh holder MH in step S260 and the mesh retainer H1 is lowered (step S270 in FIG. 6), the back surface of the mesh MS is in contact with the upper surface 1A of the mesh holder MH on which the mesh MS is mounted. In other words, a distance between the back surface of the mesh MS and the upper surface 1A of the mesh holder MH is 0 mm.

Subsequently, in a state in which the back surface of the mesh MS and the upper surface 1A of the mesh holder MH are in contact with each other, the cylinder of the mesh holder MH is lowered, and the mesh MS is retained by the mesh retainer H1 (step S270 in FIG. 6). Accordingly, the mesh MS is fixed (mounted) to the mesh holder MH. A spring CS1 is embedded in the hole 17 in a bottom surface of the support pole 15 constituting the conveying unit MP. When the back surface of the mesh MS is pressed against the upper surface 1A of the mesh holder MH, the mesh MS and the adsorption nozzle 16 in the hole 17 are biased downward by the spring CS1. Accordingly, even when the support pole 15 of the conveying unit MP moves up and down by a small amount, it is possible to prevent a gap from being generated between the upper surface 1A and the mesh MS. That is, the mesh MS can be fixed by the mesh retainer H1 while the back surface of the mesh MS is pressed against the upper surface 1A of the mesh holder MH without applying a load to the mesh holder MH or the like. The spring CS1 may be another elastic body.

Steps S170 to S270 shown in FIG. 6 as described above are repeated the same number of times as the number of meshes MS mounted on the mesh holder MH. That is, the processing returns from step S270 to step S170.

Next, a mesh holder conveying operation shown in FIG. 7, that is, an operation of conveying the mesh holder MH into the FIB-SEM device is performed. When the mesh MS is conveyed into the FIB-SEM device, the mesh MS is conveyed in a state of being mounted on the mesh holder MH.

First, the table HT (see FIG. 2) on which the mesh holder is mounted is raised (step S280 in FIG. 7).

Subsequently, the fixing between the mesh holder MH and the table HT is released (step S290 in FIG. 7).

Subsequently, the mesh holder MH is fixed to CTS-ARM (not shown) which is an arm (conveying unit) for conveying the mesh holder MH into the FIB-SEM device (step S300 in FIG. 7).

Subsequently, the table HT is lowered, and accordingly, the mesh holder MH is transferred from the table HT to the CTS-ARM (step S310 in FIG. 7).

Subsequently, the CTS-ARM is inserted into the FIB-SEM device (step S320 in FIG. 7).

Subsequently, after the mesh holder MH is received by a mesh holder MH receiving mechanism (not shown) in the FIB-SEM device, the fixing of the mesh holder MH by the CTS-ARM is released (step S330 in FIG. 7).

Subsequently, the CTS-ARM is retracted from inside the FIB-SEM device to outside the FIB-SEM device (step S340 in FIG. 7).

Thereafter, the sample piece processed and taken out in the FIB-SEM device is transferred to the pillars PL of the mesh MS mounted on the mesh holder MH in the FIB-SEM device, and the sample piece is observed (analyzed) by the SEM. That is, the automatic microsampling is performed.

Here, the conveying of the mesh holder MH into the FIB-SEM device by a conveying arm or the like is described, but the mesh holder MH may be removed from the table HT by a hand of the operator, and the conveying of the mesh holder MH into the FIB-SEM device may be manually performed.

As a general flow of the automatic microsampling, first, deposition processing (protective film preparation) is performed by spraying a deposition gas to a bulk sample such as a semiconductor substrate. Subsequently, etching processing for extracting a sample piece from the bulk sample is performed to prepare a sample piece. Subsequently, a needle for sample piece extraction is brought close to the sample piece, and the needle and the sample piece are bonded by the deposition processing.

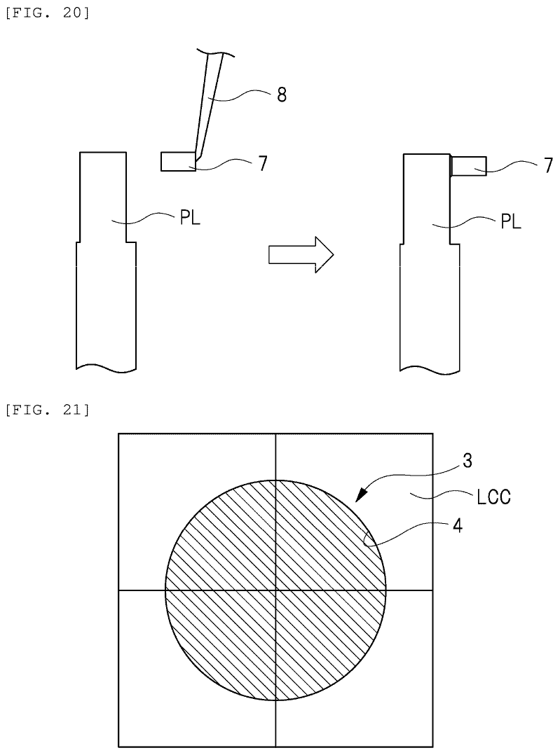

Subsequently, a portion where the bulk sample and the sample piece are connected is cut, and the sample piece is cut off. Subsequently, the pillar PL of the mesh MS to which the sample piece is to be transferred is automatically recognized by image recognition. Subsequently, as shown on the left side of FIG. 20, the positions of the pillar PL and the sample piece 7 are automatically recognized, and the needle 8 is brought close to the pillar PL. Subsequently, as shown on the right side of FIG. 20, after the pillar PL and the sample piece 7 are subjected to the deposition processing, the needle 8 and the sample piece 7 are separated from each other.

The above is the general flow of the automatic microsampling by the FIB-SEM. Next, as shown in FIG. 8, a recovery operation of the mesh holder MH is performed. The operation is performed in a reverse order of the operation described with reference to FIG. 7.

That is, the CTS-ARM is inserted into the FIB-SEM device (step S400 in FIG. 8).

Subsequently, the mesh holder MH in the FIB-SEM device is fixed to the CTS-ARM (step S410 in FIG. 8).

Subsequently, the CTS-ARM is retracted from inside the FIB-SEM device to outside the FIB-SEM device (step S420 in FIG. 8).

Subsequently, the table HT is raised (step S430 of FIG. 8).

Subsequently, the fixing between the mesh holder MH and the CTS-ARM is released (step S440 in FIG. 8).

Subsequently, the mesh holder MH is fixed to the table HT (step S450 in FIG. 8).

Subsequently, the table HT is lowered, thereby recovering the mesh holder MH (step S460 in FIG. 8).

Next, a mesh recovery operation shown in FIG. 9 is performed.

That is, the conveying unit MP is moved to the mesh holder MH (step S470 in FIG. 9).

Subsequently, the conveying unit MP adsorbs the mesh MS to be collected (step S480 in FIG. 9).

Subsequently, in a state in which the mesh MS is adsorbed, the cylinder HC and the mesh retainer H1 of the mesh holder MH are raised (step S490 in FIG. 9).

Subsequently, the conveying unit MP is moved to extract the mesh MS from the mesh holder MH, and the conveying unit MP adsorbing the mesh MS is moved to immediately above the camera (lower camera) C1 (region SH1) (step S500 in FIG. 9). In this manner, the conveying unit MP picks up the mesh MS.

Subsequently, after the mesh MS is extracted from the mesh holder MH in step S500, the cylinder HC and the mesh retainer H1 are lowered (step S510 in FIG. 9).

Subsequently, the back surface of the mesh MS is imaged by the camera (lower camera) C1 (step S520 in FIG. 9).

Subsequently, the image captured by the camera C1 in step S520 is transmitted to the control unit 1, and the control unit 1 performs image processing (step S530 in FIG. 9).

Subsequently, the stage ST is moved so that the placement table LCC serving as a collection destination comes directly below the camera (upper camera) C2 (step S540 in FIG. 9).

Subsequently, the placement portion 3 (recess 4) of the placement table LCC is imaged by the camera (upper camera) C2 (step S550 in FIG. 9). The image is transmitted to the computer to calculate a hole center. Correction calculation of the conveying unit MP is performed such that the hole center coincides with the center of the mesh MS to be collected.

Subsequently, the conveying unit MP is moved based on the correction calculation (step S560 in FIG. 9). Accordingly, the positional deviation of the mesh MS held by the conveying unit MP is corrected.

Subsequently, the adsorption of the mesh MS is released, and the mesh MS is collected on the placement table LCC (step S570 in FIG. 9). If the mesh MS sticks to the adsorption nozzle of the conveying unit MP, the adsorption release of the mesh MS is repeated.

The operations of steps S470 to S570 are repeated until all the meshes MS to be collected are collected.

Next, with reference to FIG. 10, a flow of image processing during conveying the mesh MS will be specifically described.

The image of the mesh MS captured by the camera (upper camera) C2 in step S180 of FIG. 5 is transmitted to the control unit 1.

Subsequently, the control unit 1 performs binarization processing to distinguish the mesh MS from the background (step S191 in FIG. 10). That is, as shown in FIG. 17, the white mesh MS and the black or other portions (hatched portions in FIG. 17) are distinguished from each other.

After the binarization processing in step S191, matching between an outer shape of the captured mesh MS and the outer shape model of the mesh MS registered in advance is performed, and the center of the mesh MS is roughly calculated (step S192 in FIG. 10). The outer shape model is prepared from a mesh having the same specifications as the mesh MS to be conveyed. At the time of model creation, the image of the mesh may be used as it is, or a shape portion that is likely to be noise may be masked and excluded from a matching target. Since the mesh MS is a half-moon shape, when the matching is successful, the center of the semicircle can be roughly calculated. The success of the matching means the load presence checking of the mesh MS.

Subsequently, the circular alignment mark AM1 (see FIG. 3) is detected (searched) from the captured image of the mesh MS (step S193 in FIG. 10). Here, first, the alignment mark AM1, which is easier to find than the triangular alignment mark AM2 (see FIG. 3), is detected from the entire captured image. The position of the alignment mark AM1 on the mesh MS is determined. When the alignment marks AM1 and AM2 are neither circular nor triangular, one of the alignment marks AM1 and AM2 that is easy to find is detected first.

When the detection of the alignment mark AM1 is completed, two pieces of coordinate information are obtained: the rough center of the mesh MS obtained by matching, and the position of the alignment mark AM1. Based on this, the position of the alignment mark AM2 is detected (step S194 in FIG. 10). The position of the alignment mark AM2 on the mesh MS is also determined. However, since it takes time to detect the alignment mark AM2 from the entire image, only a periphery of the position of the alignment mark AM2 estimated based on the position of the alignment mark AM1 and the center position of the mesh MS is detected. Accordingly, a time required to detect the two alignment marks AM1 and AM2 can be shortened.

Subsequently, the control unit 1 calculates the center of the mesh MS and the rotational deviation based on the positions of the alignment marks AM1 and AM2 (step S195 in FIG. 10). The center position calculated from the alignment marks AM1 and AM2 is more accurate than the center position calculated by the outer shape matching, and highly accurate conveyance can be expected. Steps S191 to S195 correspond to the image processing in step S190 in FIG. 6.

The deviation of the center position of the mesh MS is calculated as 1 to a plurality of pixels of the image captured by the camera C2. A distance fed back to the conveying unit MP can be calculated based on a distance per pixel. Based on a calculation result, the conveying unit MP is moved from a center of the camera angle of view which is a reference pickup position to an offset position (step S201 in FIG. 10). At the same time, if the mesh MS is rotating (has rotational deviation), the adsorption nozzle at the tip end of the conveying unit MP is rotated according to a rotation amount (step S202 in FIG. 10). Steps S201 and S202 correspond to the movement of the conveying unit MP in step S200 of FIG. 6, that is, the correction of the positional deviation and the rotational deviation.

Subsequently, adsorption of the mesh MS is performed (step S210 in FIG. 10).

Subsequently, in order to capture an image of the back surface of the mesh MS, the camera moves to above the lower camera (step S220 in FIG. 10).

Next, similarly to the above-described operation, imaging is performed using the lower camera, the binarization processing of the back surface of the mesh MS, the outer shape matching, and the detection of each alignment mark are performed, and the mesh MS is conveyed to the mesh holder MH.

That is, the back surface of the mesh MS is imaged by the camera C1 (step S230 in FIG. 10). The image of the mesh MS captured by the camera (lower camera) C1 in step S230 is transmitted to the control unit 1.

Subsequently, the control unit 1 performs the binarization processing (step S241 in FIG. 10).

Subsequently, matching between the outer shape of the imaged mesh MS and the outer shape model of the mesh MS registered in advance is performed, and the center of the mesh MS is roughly calculated (step S242 in FIG. 10).

Subsequently, the circular alignment mark AM1 is detected based on the captured image of the mesh MS (step S243 in FIG. 10). Here, first, the alignment mark AM1 is detected based on the entire image captured from the back side of the mesh MS.

Subsequently, the position of the alignment mark AM2 is detected based on two pieces of coordinate information about the rough center of the mesh MS and the position of the alignment mark AM1 obtained from the matching (step S244 in FIG. 10). The alignment mark AM1 requiring a relatively short detection time is detected before the alignment mark AM2. Accordingly, the time required to detect the two alignment marks AM1 and AM2 can be shortened.

Subsequently, the control unit 1 calculates the center of the mesh MS and the rotational deviation based on the positions of the alignment marks AM1 and AM2 (step S245 in FIG. 10). Steps S241 to S245 correspond to the image processing in step S240 in FIG. 6.

Subsequently, the cylinder HC of the mesh holder MH is raised to form a gap between the mesh retainer H1 and the upper surface 1A of the main body 5 of the mesh holder MH (step S250 in FIG. 10).

The deviation of the center position of the mesh MS is calculated as 1 to a plurality of pixels of the image captured by the camera C1. The distance fed back to the conveying unit MP can be calculated based on the distance per pixel. Based on the calculation result, the conveying unit MP is moved from the center of the camera angle of view which is the reference pickup position to the offset position (step S261 in FIG. 10). At the same time, if the mesh MS is rotating (has rotational deviation), the adsorption nozzle at the tip end of the conveying unit MP is rotated according to the rotation amount (step S262 in FIG. 10). Steps S261 and S262 correspond to the movement of the conveying unit MP in step S260 of FIG. 6, that is, the correction of the positional deviation and the rotational deviation.

Subsequently, in a state in which the back surface of the mesh MS and the upper surface 1A of the mesh holder MH are in contact with each other, the cylinder of the mesh holder MH is lowered, and the mesh MS is retained by the mesh retainer H1 (step S270 in FIG. 10). Accordingly, the mesh MS is fixed (mounted) to the mesh holder MH.

Subsequently, the adsorption of the mesh MS is released (step S271 in FIG. 10).

Subsequently, the conveying unit MP is moved to a standby position (step S272 in FIG. 10).

Next, a flow of the recovery operation of the mesh MS performed after the automatic microsampling by the FIB-SEM will be specifically described with reference to FIG. 11. In the recovery operation, either the flow using the upper camera or the flow using the lower camera may be performed first, and these flows may be performed simultaneously.

Here, first, S480 to S520 described with reference to FIG. 9 are performed (steps S480 to S520 in FIG. 11). Subsequently, steps S531 to S535, which are processing steps of the image captured by the lower camera, are performed in the same procedure as steps S241 to S245 described with reference to FIG. 10.

The camera (upper camera) C2 is used to capture an image of the recess 4, which is the placement portion 3 of the placement table LCC serving as the collection destination of the mesh MS (step S550 in FIG. 11). An imaging condition at this time is different from that when the mesh MS is in the recess 4, and a condition for imaging brighter is applied.

Subsequently, the image captured in step S550 is transmitted to the control unit 1, and the control unit 1 performs the binarization processing (step S551 in FIG. 11). Accordingly, it is easy to distinguish between a flat surface portion which is an uppermost surface of the placement table LCC and the recess 4. That is, as shown in FIG. 21, in the image captured in step S550, the inside of the recess 4 is displayed in black, and the flat surface portion which is the uppermost surface of the placement table LCC outside the recess 4 is displayed in white.

When the recess 4 is recognized, the center of the circular hole is calculated (step S552 in FIG. 11). The coordinate is a target coordinate for collecting the mesh MS. In FIG. 21, the center position of the circular recess 4 is deviated from the center of the camera angle of view, which is a reference placement position (a reference position before correction of the conveying unit MP).

Steps S550 to S552 described above may be performed at any time point before or after steps S490 to S535, or may be performed in the middle of steps S490 to S535. Steps S550 to S552 may be performed at any time point as long as the stage ST and the placement table LCC are moved (rotated) last before step S535 described below is performed. For example, when the stage ST and the placement table LCC are not moved (rotated) even once after the mesh MS is picked up from the placement table LCC in step S220 of FIG. 6, steps S550 to S552 may be performed at any time point after step S220.

Next, by performing both steps S535 and S552, the center position of the mesh MS obtained by the lower camera is calculated, and when the center position of the recess 4 is calculated by the upper camera, the conveying unit MP is moved such that the center positions coincide with each other, thereby correcting the positional deviation between the mesh MS and the recess 4 (step S553 in FIG. 11). At this time, the rotational deviation of the mesh MS may be corrected.

Subsequently, in a state in which the mesh MS is placed at the center of the recess 4, the adsorption of the mesh MS by the conveying unit MP is released (step S570 in FIG. 11). Accordingly, the collection of the mesh MS is completed.

Subsequently, the conveying unit MP is moved to the standby position (step S571 in FIG. 11).

### Effects of Present Embodiment

Effects of the present embodiment will be described below with reference to FIGS. 26 and 27 of a comparative example.

As a method for mounting (fixing) the mesh on the mesh holder, it is conceivable to convey and fix the mesh onto the mesh holder by a human hand. In this case, it is conceivable to use a jig for holding the mesh during conveying or a guide for moving the mesh to a mounting position on the mesh holder. However, since the conveying is performed manually, there is a problem that conveying accuracy is not stable. That is, as in the mesh MS1 shown in FIG. 26, the mesh MS1 is not straight fixed to the mesh holder MH1, and there is a possibility that the positional deviation and the rotational deviation occur. In the comparative example shown in FIG. 26, meshes MS1 to MS3 are fixed by the mesh retainers H1 by a person tightening screws S1.

In addition, a case in which dirt adheres as in the mesh MS2, a case in which deformation or breakage occurs as in the mesh MS3, a case in which damage is attached, and the like may occur. Further, the mesh may be dropped or lost. However, only the problem of positional accuracy is mainly focused here.

In the automatic microsampling performed by the FIB-SEM, a pillar position of an LC is automatically recognized, and similarly, a sample piece at a tip end of the needle whose position is automatically recognized is brought close to the pillar and bonded. However, when conveying positional accuracy of the mesh with respect to the mesh holder is poor, there is a possibility that the sample piece is not included in an observation visual field range by a charged particle beam (FIB or SEM) and an adhesion of the sample piece fails.

In addition, in the conveying positional accuracy of the mesh, particularly, in a case in which there is a deviation in the rotation direction, when the sample piece is to be brought close to a corner of the tip end of the pillar which is the target, as shown in FIG. 27, a middle portion of the pillar PL and a corner portion of the sample piece 7 collide with each other before the sample piece approaches the target, and the adhesion may fail. When the middle portion of the pillar PL collides with the corner portion of the sample piece 7, the sample piece 7 may peel off from the needle 8, and the sample piece 7 may be lost. In order to avoid such an error, it is necessary to accurately mount the mesh on the mesh holder.

Therefore, in the conveyance device according to the present embodiment, the mesh MS is automatically conveyed from the placement table LCC to the mesh holder MH using the conveying unit MP. The conveyance can be efficiently performed by automatically performing the conveyance without manually performing the conveyance. Here, the mesh MS held by the conveying unit MP is imaged by the camera (lower camera) C1, the positional deviation amount and the rotational deviation amount of the mesh MS are calculated based on the image acquired by the imaging, and the correction is performed by moving and rotating the conveying unit MP based on a calculation result. Accordingly, the conveying accuracy of the mesh MS is improved, and it is possible to prevent the positional deviation and the rotational deviation from occurring when the mesh MS is mounted on the mesh holder MH.

The mesh MS mounted on the placement table is imaged by the camera (upper camera) C2, the positional deviation amount and the rotational deviation amount of the mesh MS are calculated based on the image acquired by the imaging, and the correction is performed by moving and rotating the conveying unit MP based on a calculation result. Accordingly, it is possible to prevent the positional deviation and the rotational deviation from occurring when the conveying unit MP picks up the mesh MS. That is, the conveying accuracy of the mesh MS is improved, and it is possible to prevent the positional deviation and the rotational deviation from occurring when the mesh MS is mounted on the mesh holder MH.

Even when the correction using the camera (upper camera) C2 is performed, there is a possibility that the positional deviation or the rotational deviation occurs due to the adsorption operation by the conveying unit MP. However, the conveying accuracy of the mesh MS can be further improved by performing correction using the camera (lower camera) C1 thereafter.

Here, also in the recovery operation of the mesh holder MH performed after the automatic microsampling by the FIB-SEM, the positional deviation is corrected using the cameras C1 and C2. When the mesh is manually conveyed from the mesh holder to the placement table in the recovery operation or when the conveying is performed by the conveying unit without performing the correction, the position of the mesh to be returned to the recess of the placement table may be deviated. In this case, the mesh may be damaged, dropped, or lost. In the present embodiment, by correcting the positional deviation using the cameras C1 and C2, damage, dropping, and loss of the mesh can be prevented, and the mesh MS can be conveyed to the center of the recess 4.

In addition, here, when the mesh MS is mounted on the mesh holder MH in steps S260 and S270 of FIG. 6, the conveying unit MP performs fixing by the mesh retainer H1 in a state in which the mesh MS is in contact with the upper surface 1A of the mesh holder MH. By bringing the mesh MS into contact with the mesh holder MH and lowering the mesh retainer H1 while performing adsorption by the conveying unit MP, it is possible to prevent the occurrence of positional deviation between the mesh MS and the mesh holder MH when the mesh MS is separated from the conveying unit MP. In order to perform the operation, the conveying unit MP and the mesh retainer H1 are formed in shapes that do not interfere with each other (see FIG. 18).

As described above, according to the conveying method and the conveyance device according to the present embodiment, the conveying accuracy of the mesh can be improved.

### Modification 1

Replenishment of the mesh to the conveying table may be performed manually. In addition, a replenishing operation can be automated using the conveying unit. However, when the mesh is manually conveyed to the placement table or when the conveying is performed by the conveying unit without performing the correction, the position of the mesh to be returned to the recess of the placement table may be deviated. In this case, the mesh may be damaged, dropped, or lost.

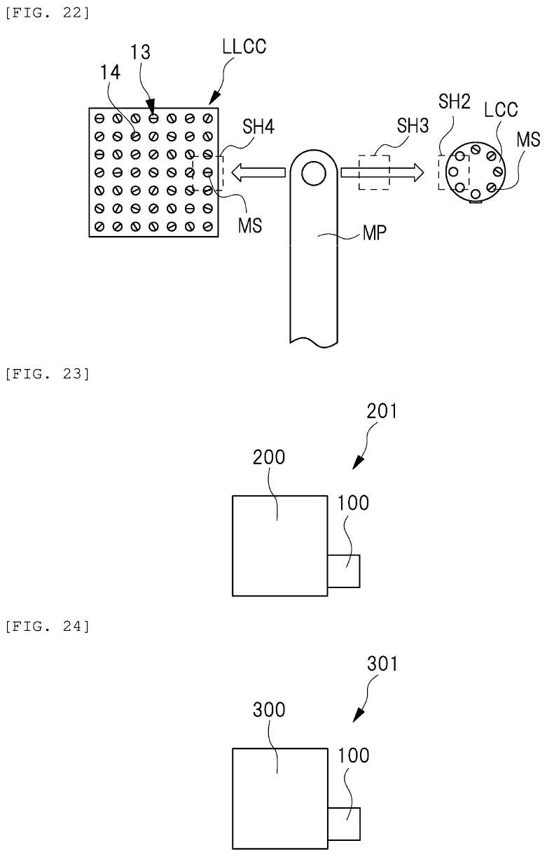

Hereinafter, when the placement table LCC shown in FIG. 1 is replenished (conveyed) with the mesh MS from, for example, a larger placement table LLCC, correction using a camera will be described with reference to FIG. 22. FIG. 22 is a plan view showing a part of a conveyance device according to a modification of the present embodiment.

The placement table LLCC shown in FIG. 22 is larger than the placement table LCC and is a cartridge on which a larger number of meshes MS can be mounted. Here, a conveying unit (not shown) connected to the control unit 1 automatically conveys the mesh MS from the placement table LLCC to the placement table LCC. That is, the mesh MS is placed in each of the plurality of recesses 14 provided on the upper surface of the placement table LLCC as the placement portion 13. The conveying unit adsorbs and picks up the mesh MS in the recess 14, conveys the mesh MS while holding the mesh MS, and then conveys the mesh MS into the recess 4 which is the placement portion 3 of the placement table LCC.

At this time, the mesh MS being conveyed by the conveying unit is imaged in a region SH3 by a camera (lower camera) (not shown), and a positional deviation amount of the mesh MS with respect to the conveying unit can be calculated by processing an image acquired by the imaging. When the conveying unit is moved (corrected) based on a calculation result, the conveying accuracy of the mesh MS to the recess 4 can be improved. The lower camera is different from the camera C1 shown in FIG. 1, and the same camera as the camera C1 may be used.

Before the conveying, the recess 4 serving as a conveying destination is imaged in the region SH2 by a camera (upper camera) (not shown), and the image acquired accordingly is processed, so that the positional deviation amount between the mesh MS held by the conveying unit and the recess 4 can be calculated. When the conveying unit is moved (corrected) based on the calculation result, the conveying accuracy of the mesh MS to the recess 4 can be improved. The upper camera may be the same as or different from the camera C2 shown in FIG. 1.

Further, before the conveying unit picks up the mesh MS, similarly to steps S180 to S200 of FIG. 5, the mesh MS in the recess 14 of a region SH4 may be imaged using an upper camera (not shown) on the placement table LLCC. By calculating the positional deviation amount between the mesh MS and the conveying unit by processing the acquired image and moving (correcting) the conveying unit based on the calculation result, it is possible to improve the conveying accuracy of the mesh MS to the recess 4. The upper camera is different from the camera C2 shown in FIG. 1.

After the mesh MS is conveyed to the placement table LCC as described above and replenished, the conveying operation or the recovery operation described with reference to FIGS. 5 to 11 is performed.

In the present modification, the mesh MS can be accurately conveyed by performing imaging by the lower camera, the image processing, and the correction in the region SH3. The conveying accuracy of the mesh MS can be further improved by performing the imaging, the image processing, and the correction in the region SH2 or SH4.

### Modification 2

The embodiment described with reference to FIGS. 1 to 19 and 21 relates to the analysis system 201 in which the mesh conveyance device 100 and the FIB-SEM device 200 are combined as shown in FIG. 23. In other words, the analysis system 201 includes the conveyance device 100 and the FIB-SEM device 200. The conveyance device 100 corresponds to the configuration shown in FIG. 1.

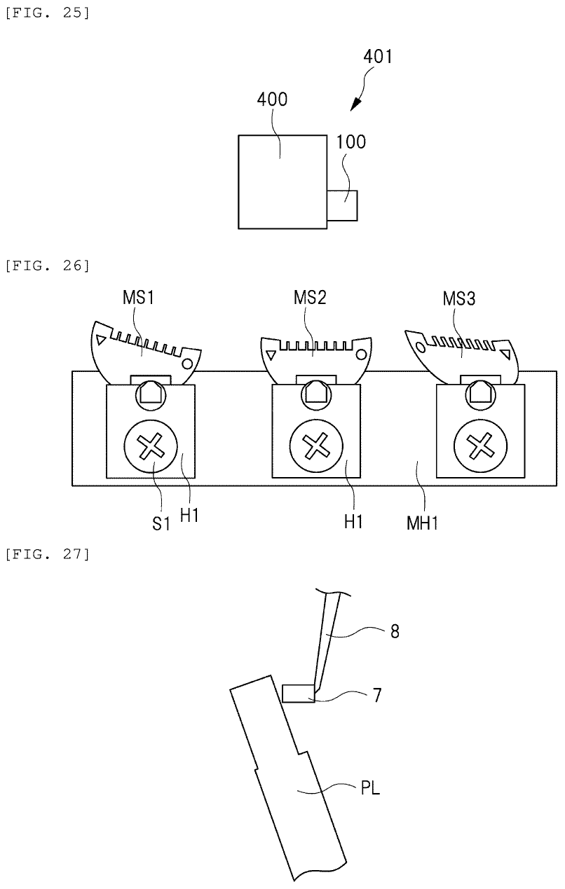

A target to which the conveyance device 100 conveys the mesh is not limited to the FIB-SEM device, and may be an optical sample piece transfer device 300 shown in FIG. 24 or a TEM device 400 shown in FIG. 25. An analysis system 301 shown in FIG. 24 includes the conveyance device 100 and the optical sample piece transfer device 300. An analysis system 401 shown in FIG. 25 includes the conveyance device 100 and the optical sample piece transfer device 300.

That is, the conveying method and the conveyance device described with reference to FIGS. 1 to 19 and 21 are used in a method for conveying a mesh from a placement table to a mesh holder in a stage before the mesh is put into the optical sample piece transfer device 300 or the TEM device 400, and a method for conveying a mesh carried out from the optical sample piece transfer device 300 or the TEM device 400 from a mesh holder to a placement table. The analysis system 301 shown in FIG. 24 may include a charged particle beam device such as a FIB-SEM device or a TEM device in addition to the optical sample piece transfer device 300.

Although the invention made by the present inventors has been specifically described above based on the embodiment, the invention is not limited to the embodiment, and various modifications can be made without departing from the gist of the invention.

### INDUSTRIAL APPLICABILITY

The invention can be widely used for a conveying method, a conveyance device, and an analysis system.

### REFERENCE SIGNS LIST

1: control unit
2: storage unit
3, 13: placement portion
4, 14: recess
5: main body
15: support pole
16: adsorption nozzle
17: hole
AM1, AM2: alignment mark
C1, C2, C3: camera
CD1, CD2: two-dimensional code
CP: cylinder pin
CS, CS1: spring
HC: cylinder
HT: table
LCC, LLCC: placement table
MH, MH1: mesh holder
MP: conveying unit
MS, MS1, MS2, MS3: mesh
PL: pillar
SH1: region
SH2: region
SH3: region
SH4: region
ST: stage
100: conveyance device
201, 301, 401: analysis system
200: FIB-SEM device
300: optical sample piece transfer device
400: TEM device

1.-18. (canceled)

19. A conveying method for conveying a mesh on which a sample to be analyzed using a charged particle beam device is to be mounted, the conveying method comprising:
(a) a step of picking up and holding the mesh placed on a first placement table by a first conveying unit;
(b) a step of capturing an image of the mesh held by the first conveying unit using a first imaging unit after the step (a);
(c) a step of correcting a position or an angle of the mesh based on a first image acquired in the step (b); and
(d) a step of mounting the mesh on a mesh holder by the first conveying unit after the step (c), wherein
in the step (d), the mesh held by the first conveying unit is fixed to the mesh holder in a state in which the mesh is in contact with a mounting surface of the mesh holder, which is a surface on which the mesh is to be mounted.

20. The conveying method according to claim 19, wherein
in the step (c), the position of the mesh is corrected by moving the first conveying unit, and in the step (d), the angle of the mesh is corrected by axially rotating the first conveying unit around an axis perpendicular to a mounting surface of the mesh holder on which the mesh is to be mounted.

21. The conveying method according to claim 19, further comprising:
(a1) a step of capturing an image of the mesh disposed on the first placement table using a second imaging unit before the step (a), wherein
in the step (a), a position or an angle of the first conveying unit with respect to the mesh is corrected based on a second image acquired in the step (a1), and the mesh is picked up.

22. The conveying method according to claim 21, wherein
in the step (a), the position of the first conveying unit with respect to the mesh is corrected by moving the first conveying unit, and the angle of the first conveying unit with respect to the mesh is corrected by axially rotating the first conveying unit around an axis perpendicular to a mounting surface of the mesh holder, which is a surface on which the mesh is to be mounted in the step (d).

23. The conveying method according to claim 19, further comprising:
(e) a step of mounting the sample on the mesh that is mounted on the mesh holder and analyzing the sample using the charged particle beam device after the step (d);
(f) a step of picking up and holding the mesh by the first conveying unit after the step (e);
(g) a step of capturing an image of the mesh held by the first conveying unit using the first imaging unit after the step (f);
(h) a step of correcting the position of the mesh based on a third image acquired in the step (g);
(i) a step of capturing an image of a mesh placement portion on an upper surface of the first placement table using a second imaging unit after the step (a);
(j) a step of correcting a position of the first conveying unit based on the third image and a fourth image acquired in the step (i); and
(k) a step of placing the mesh on the mesh placement portion by the first conveying unit after the step (j).

24. The conveying method according to claim 19, further comprising:
(a1) a step of conveying the mesh placed on a second placement table to the first placement table before the step (a), wherein
the step (a1) further includes
(a2) a step of picking up and holding the mesh placed on the second placement table by a second conveying unit,
(a3) a step of capturing an image of the mesh held by the second conveying unit using a third imaging unit after the step (a2),
(a4) a step of capturing an image of a mesh placement portion on an upper surface of the first placement table using a second imaging unit,
(a5) a step of correcting a position of the second conveying unit based on a fifth image acquired in the step (a3) and a sixth image acquired in the step (a4), and
(a6) a step of placing the mesh on the mesh placement portion by the second conveying unit after the step (a5).

25. The conveying method according to claim 19, wherein
the mesh includes a first alignment mark and a second alignment mark, and
in the step (c), the second alignment mark is detected after the first alignment mark is detected from the first image, a center position of the mesh is calculated based on a position of the first alignment mark and a position of the second alignment mark, and the position or the angle of the mesh is corrected based on information about the position of the first alignment mark, the position of the second alignment mark, and the center position.

26. A conveyance device comprising:
a placement table on which a mesh on which a sample to be analyzed using a charged particle beam device is to be mounted is placeable;
a mesh holder on which the mesh is mountable;
a first conveying unit configured to convey the mesh between the placement table and the mesh holder;
a first imaging unit configured to capture an image of the mesh held by the first conveying unit; and
a control unit configured to correct a position or an angle of the mesh based on a first image acquired by the first imaging unit, wherein
the mesh holder includes a main body and a mesh retainer operable in a direction perpendicular to a mounting surface of the main body, which is a surface on which the mesh is to be mounted, and
the mesh holder sandwiches the mesh by moving the mesh retainer to a mounting surface side in a state in which the mesh held by the first conveying unit is in contact with the mounting surface, thereby fixing the mesh to the mesh holder.

27. The conveyance device according to claim 26, wherein
the control unit corrects the position of the mesh by moving the first conveying unit, and corrects the angle of the mesh by axially rotating the first conveying unit around an axis perpendicular to a mounting surface of the mesh holder on which the mesh is to be mounted.

28. The conveyance device according to claim 26, further comprising:
a second imaging unit configured to capture an image of the mesh placed on the placement table, wherein
the control unit corrects a position or an angle at which the first conveying unit picks up the mesh placed on the placement table based on a second image acquired by the second imaging unit, and corrects the position or the angle of the mesh based on the first image acquired by the first imaging unit, and
the first conveying unit conveys the mesh whose position or angle is corrected based on the first image and mounts the mesh on the mesh holder.

29. The conveyance device according to claim 26, further comprising:
a second imaging unit configured to capture an image of a mesh placement portion on an upper surface of the placement table, wherein
the control unit corrects, based on a third image acquired by the second imaging unit and the first image acquired by the first imaging unit by capturing an image of the mesh picked up by the first conveying unit from the mesh holder, the position of the mesh such that a center of the mesh and a center of the mesh placement portion coincide with each other, and
the first conveying unit conveys the mesh whose position is corrected based on the third image and the first image and places the mesh on the placement table.

30. The conveyance device according to claim 26, further comprising:
a second imaging unit configured to capture an image of a first identification code provided on a front surface of the mesh; and
a storage unit connected to the control unit, wherein
the control unit causes the storage unit to store information of the first identification code acquired from a third image acquired by the second imaging unit.

31. The conveyance device according to claim 30, further comprising:
a third imaging unit configured to capture an image of a second identification code provided on the placement table, wherein
the control unit causes the storage unit to store information about the first identification code and information about the second identification code acquired from a fourth image acquired by the third imaging unit in association with each other.

32. The conveyance device according to claim 26, wherein
the mesh holder includes a main body and a mesh retainer operable in a direction perpendicular to a mounting surface of the main body, which is a surface on which the mesh is to be mounted,
the mesh is fixable by sandwiching the mesh between the mesh retainer and the mounting surface, and
the mesh retainer and the first conveying unit do not interfere with each other.

33. The conveyance device according to claim 26, wherein
the first conveying unit includes an elastic body that, when a back surface of the held mesh is pressed against an upper surface of the mesh holder, biases the mesh toward an upper surface side of the mesh holder.

34. An analysis system comprising:
the conveyance device according to claim 26; and
a charged particle beam device and/or an optical sample piece transfer device.
